(19) United States
(12) Patent Application Publication
(10) Pub. No.: US 2023/0212327 A1
(43) Pub. Date: Jul. 6, 2023

(54) UV CURABLE FORMULATIONS CONTAINING DIPROPYLENE GLYCOL DIACRYLATE

(71) Applicant: BASF SE, Ludwigshafen am Rhein (DE)

(72) Inventors: Herve DIETSCH, Wyandotte, MI (US); Nathan Dane WOOD, Wyandotte, MI (US); Lu ZHANG, Tarrytown, NY (US); John STEWART, Wyandotte, MI (US)

(21) Appl. No.: 17/927,761

(22) PCT Filed: May 27, 2021
(86) PCT No.: PCT/US2021/034596

§ 371 Date: Nov. 25, 2022

Related U.S. Application Data
(60) Provisional application No. 63/032,208, filed on May 29, 2020.

(51) Int. Cl. C08F 2/50; C08F 222/10; B29C 64/112; B29C 64/129

(52) U.S. Cl. CPC C08F 2/50; C08F 222/102; C08F 222/1065; B29C 64/112; B29C 64/129; B33Y 10/00

(57) ABSTRACT

Described herein are photopolymerizable compositions for use in 3D printing. The compositions contain dipropylene glycol diacrylate and one or more urethane acrylate oligomers, optionally with a photoinitiator. Also described are methods for fabricating three dimensional objects utilizing these compositions, and three dimensional objects made from these compositions.

### TECHNICAL FIELD

The present disclosure relates to three dimensional (3D) printing technology, and, more specifically, it is related to 3D compositions for inkjet, stereolithography (SLA), and Digital Light Processing (DLP), and methods of use and preparation thereof.

### BACKGROUND OF THE INVENTION

In the discussion of the background that follows, reference is made to certain structures and/or methods. However, the following references should not be construed as an admission that these structures and/or methods constitute prior art. Applicant expressly reserves the right to demonstrate that such structures and/or methods do not qualify as prior art.

Photocurable compositions are materials used in 3D printing techniques using light source(s) to cure (polymerize) a network of a monomer and oligomer, initiating radical polymerization using a photoinitiator. Generally, these compositions contain photoinitiators, monomers, oligomers, and other components. Typically, in order to reach desired toughness, it is required to incorporate six different components (monomers/oligomers) in a clear formulation.

There remains a desire to provide 3D printing formulations which improve upon other formulations in desirable properties in the field, such as toughness. It further remains a desire to provide formulations which are able to provide these benefits while limiting the number of components (monomers/oligomers), so as to provide benefit in cost and resource use.

It was surprisingly found that the use of dipropylene glycol diacrylate, rather than the more customary monofunctional monomers or even other similar multifunctional acrylate monomers, in combination with a urethane acrylate oligomer, led to compositions which demonstrated significantly improved toughness. It was further surprisingly found that the use of these formulations enabled the production of clear formulations which enabled adequate toughness in the resultant product while minimizing the number of components to three (one photoinitiator, one monomer, and one oligomer).

### BRIEF SUMMARY OF THE INVENTION

One aspect of the present technology relates to a composition which includes one or more urethane acrylate oligomers and DPGDA, wherein the composition is a 3D UV curable composition.

In another aspect of the present technology the 3D UV curable composition contains DPGDA as sole monomer. In another aspect, the composition contains only a single oligomer. In a third aspect, the composition contains DPGDA as sole monomer, a single urethane acrylate oligomer, and a single photoiniator.

Another aspect is a composition which includes 0.5 to 99.5% by weight of DPGDA, based on the combination of DPGDA and urethane acrylate oligomer. Optionally, the composition may include 10 to 90, 20 to 80, 25 to 75, 30 to 70, or 40 to 60% by weight of DPGDA, based on the combination of DPGDA and urethane acrylate oligomer.

In any embodiments, the compositions may be useful for inkjet, SLA, and/or DLP deposition. In any embodiments, the composition may include one or more photoinitiators. The present technology also provides a package that includes any of the compositions described herein.

In another aspect, the present technology relates to a method for preparing a 3D article using the compositions described in any embodiment herein, the method includes applying successive layers of one or more of the compositions described herein in any embodiment to fabricate a 3D article; and irradiating the successive layers with UV irradiation. In any embodiments, the composition may be inkjet, SLA, and/or DLP deposited.

In yet another related aspect, the present technology provides a 3D article that includes UV cured successive layers of any of the compositions described herein. In any embodiments, the compositions may be deposited by inkjet, SLA, or DLP.

In a first aspect of the invention, the present technology provides a photopolymerizable composition comprising: dipropylene glycol diacrylate; and at least one urethane acrylate oligomer.

In a second aspect, the present technology provides the photopolymerizable composition according to the first aspect, wherein the at least one urethane acrylate oligomer is represented by Formula (I):

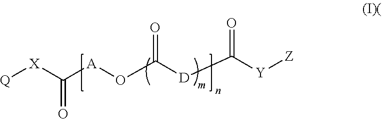

wherein:

A is derived from one or more poly hydroxyl group compounds having a molecular weight less than about I 000 g/mol;

D, X, and Y are independently urethane or carbamate linkages derived from one or more polyisocyanates;

Q and Z are independently derived from one or more compounds having at least one ethylenically unsaturated group;

n is an integer from 1 to 20; and

m is an integer from 0 to 20.

In a third aspect, the technology provides the photopolymerizable composition according to either the first or the second aspect, wherein the composition comprises 0.5 to 99.5% by weight dipropylene glycol diacrylate, based on the amount of dipropylene glycol diacrylate and urethane acrylate oligomer,

In a fourth aspect, the technology provides the photopolymerizable composition according to any one of the first, second, or third aspect, wherein the composition comprises 25 to 75% by weight dipropylene glycol diacrylate, based on the amount of dipropylene glycol diacrylate and urethane acrylate oligomer.

In a fifth aspect, the technology provides the photopolymerizable composition according to any one of the first four aspects, wherein the composition further comprises one or more photoinitiators.

In a sixth aspect, the technology provides the photopolymerizable composition according to any one of the first five aspects, wherein the one or more photoinitiators is selected from the group consisting of bis(2,4,6-trimethylbenzoyl)-phenylphosphine oxide, 2,4,6-trimethylbenzoylphenyl phosphinate, bis(2,6-dimethoxybenzoyl)-2,4,4-trimethylpentylphosphine oxide, diphenyl(2,4,6-trimethylbenzoyl)phosphine oxide, alpha-hydroxy cyclohexyl phenyl ketone, 2-hydroxy-1-(4-(4-(2-hydroxy-2-methylpropionyl)benzyl)phenyl-2-methylpropan-1-one, 2-hydroxy-2-methyl-1-phenylpropanone, 2-hydroxy-2-methyl-1-(4-isopropylphenyl)propanone, oligo (2-hydroxy-2-methyl-1-(4-(1-methylvinyl)phenyl)propanone, 2-hydroxy-2-methyl-1-(4-dodecylphenyl)propanone, 2-hydroxy-2-methyl-1-[(2-hydroxyethoxy)phenyl]propanone, benzophenone, substituted benzophenones, and mixtures of any two or more thereof.

In a seventh aspect, the technology provides the photopolymerizable composition according to the sixth aspect, wherein the one or more photoinitiators are selected from the group consisting of diphenyl(2,4,6-trimethylbenzoyl)phosphine oxide, ethyl(2,4,6-trimethylbenzoyl)phenylphosphinate, 1-hydroxycyclohexylphenylketone, and combinations of two or more thereof.

In an eighth aspect, the technology provides the photopolymerizable composition according to the sixth or seventh aspect, wherein the one or more photoinitiators are present in the composition in an amount of from 0.01 to 6 weight percent, based on the total weight of the composition.

In a ninth aspect, the technology provides the photopolymerizable composition according to the sixth or seventh aspect, wherein the one or more photoinitiators are present in the composition in an amount of from 1 to 2 weight percent, based on the total weight of the composition.

In a tenth aspect, the technology provides the photopolymerizable composition according to any one of the first through ninth aspects, wherein DPGDA is the sole monomer present in the composition.

In an eleventh aspect, the technology provides the photopolymerizable composition according to the tenth aspect, wherein the one or more urethane acrylate oligomers are the sole oligomers present in the composition.

In a twelfth aspect, the technology provides the photopolymerizable composition according to the seventh aspect, wherein the composition consists of the DPGDA, the one or more urethane acrylate oligomer, and the one or more photoinitiators.

In a thirteenth aspect, the technology provides the photopolymerizable composition according to any one of the first through eleventh aspects, wherein the composition further comprises a solvent.

In a fourteenth aspect, the technology provides a package comprising the composition of any one of the first through thirteenth aspects.

In a fifteenth aspect, the technology provides a method of preparing a three-dimensional article, wherein the method comprises applying successive layers of one or more of the compositions of any one of the first through thirteenth aspects to fabricate a three-dimensional article, and irradiating the successive layers with UV irradiation.

In a sixteenth aspect, the technology provides the method of the fifteenth aspect, wherein the applying comprises depositing a first layer of the composition to a substrate and applying a second layer of the composition to the first layer and optionally applying successive layers thereafter.

In a seventeenth aspect, the technology provides the method of the fifteenth or sixteenth aspect, wherein the applying comprises ink jet printing of the composition.

In an eighteenth aspect, the technology provides a three-dimensional article comprising UV cured successive layers of the composition of any one of the first through thirteenth aspects.

In a nineteenth aspect, the technology provides a three-dimensional article produced by the method of the fifteenth, sixteenth, or seventeenth aspect.

### Definitions

Prior to describing the invention in further detail, the terms used in this application are defined as follows unless otherwise indicated.

As used herein, “about” will be understood by persons of ordinary skill in the art and will vary to some extent depending upon the context in which it is used. If there are uses of the term which are not clear to persons of ordinary skill in the art, given the context in which it is used, “about” will mean up to plus or minus 10% of the particular term.

The use of the terms “a” and “an” and “the” and similar referents in the context of describing the elements (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the embodiments and does not pose a limitation on the scope of the claims unless otherwise stated. No language in the specification should be construed as indicating any non-claimed element as essential.

“Optional” or “optionally” means that the subsequently described circumstance may or may not occur, so that the description includes instances where the circumstance occurs and instances where it does not.

The term “pre-determined” refers to an element whose identity is known prior to its use.

As used herein, the term “Stereolithography” or “SLA” refers to a form of 3D printing technology used for creating models, prototypes, patterns, and production of parts in a layer-by-layer fashion using photopolymerization, a process by which light causes chains of molecules to link, forming polymers. Those polymers then make up the body of a three-dimensional solid.

As used herein, the term “Digital Light Processing” or “DLP” refers to an additive manufacturing process, also known as 3D printing and stereolithography, which takes a design created in a 3D modeling software and uses DLP technology to print a 3D object. DLP is a display device based on optical micro-electro-mechanical technology that uses a digital micromirror device. DLP may use as a light source in printers to cure resins into solid 3D objects.

### DETAILED DESCRIPTION OF THE INVENTION

Before the present invention is described in greater detail, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Certain ranges are presented herein with numerical values being preceded by the term “about.” The term “about” is used herein to provide literal support for the exact number that it precedes, as well as a number that is near to or approximately the number that the term precedes. In determining whether a number is near to or approximately a specifically recited number, the near or approximating unrecited number may be a number which, in the context in which it is presented, provides the substantial equivalent of the specifically recited number.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are now described.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

Disclosed is a composition for use in three dimensional printing by way of photopolymerization.

Provided herein are UV curable compositions containing, as monomer, dipropylene glycol diacrylate (DPGDA):

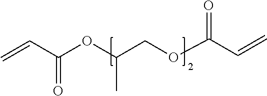

While DPGDA has been used in inks or coatings, it has surprisingly been found by way of the photopolymerizable compositions for 3D printing disclosed herein it is possible to produce 3D structures with improved toughness, while minimizing the number of components normally required in such compositions. These compositions can be printed using inkjet print heads or other 3D printing techniques (e.g., SLA and/or DLP), and offer enhanced toughness in the resultant product.

It has surprisingly been found that DPGDA, when compared to either more traditionally used monofunctional monomers, or even similar multifunctional acrylate monomers, create products of a high degree of toughness while minimizing cost through the use of fewer materials.

In the photopolymerizable 3D printing compositions disclosed herein, DPGDA is used in combination with at least one urethane acrylate oligomer. Urethane acrylate oligomers include, for example, commercially available urethane-acrylate oligomers. Exemplary urethane acrylates of this type are derived from the group consisting of polyether, polyester, polycarbonate, alkyl or aryl polyols, alkyl or aryl polyisocyanates, hydroxyl functional (meth)acrylates, and blends of polyols and/or isocyanates.

Urethane acrylate oligomers are, for example, obtained by the reaction of polyols with diisocyanates and capped by acrylates. In the alternative it is possible to obtain urethane acrylates via the reaction of a hydroxyalkylacrylate with an isocyanate. Hydroxyalkylacrylates useful for such a reaction are represented by the below formula

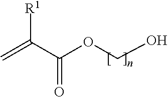

Where R¹ is H or a Ci-05 alkyl group, and n is a number from 1 to 10.

Exemplary urethane acrylate oligomers are represented by the below formula (I):

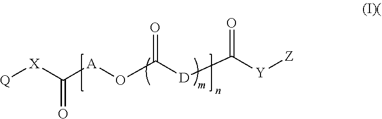

wherein:

A is derived from one or more poly hydroxyl group compounds having a molecular weight less than about 30,000 g/mol, optionally less than about 5,000 g/mol, optionally less than about 2,000 g/mol; molecular weight is optionally greater than about 500 g/mol;

D, X, and Y are independently urethane or carbamate linkages derived from one or more polyisocyanates;

Q and Z are independently derived from one or more compounds having at least one ethylenically unsaturated group;

n is an integer from 1 to 20; and

m is an integer from 0 to 20.

These oligomers and methods for their manufacture are set forth in WO 2019/070587, incorporated herein by reference.

As used herein, the term (meth)acrylic or (meth)acrylate refers to acrylic or methacrylic acid, esters of acrylic or methacrylic acid, and salts, amides, and other suitable derivatives of acrylic or methacrylic acid, and mixtures thereof. Illustrative examples of suitable (meth)acrylic monomers include, without limitation, the following methacrylate esters: methyl methacrylate, ethyl methacrylate, n-propyl methacrylate, n-butyl methacrylate (BMA), isopropyl methacrylate, isobutyl methacrylate, n-amyl methacrylate, n-hexyl methacrylate, isoamyl methacrylate, 2-hydroxyethyl methacrylate, 2-hydroxypropyl methacrylate, N,N-dimethylaminoethyl methacrylate, N,N-diethylaminoethyl methacrylate, t-butylaminoethyl methacrylate, 2-sulfoethyl methacrylate, trifluoroethyl methacrylate, glycidyl methacrylate (GMA), benzyl methacrylate, allyl methacrylate, 2-n-butoxyethyl methacrylate, 2-chloroethyl methacrylate, sec-butyl-methacrylate, tert-butyl methacrylate, 2-ethylbutyl methacrylate, cinnamyl methacrylate, crotyl methacrylate, cyclohexyl methacrylate, cyclopentyl methacrylate, 2-ethoxyethyl methacrylate, furfuryl methacrylate, hexafluoroisopropyl methacrylate, methallyl methacrylate, 3-methoxybutyl methacrylate, 2-methoxybutyl methacrylate, 2-nitro-2-methylpropyl methacrylate, n-octylmethacrylate, 2-ethylhexyl methacrylate, 2-phenoxyethyl methacrylate, 2-phenylethyl methacrylate, phenyl methacrylate, propargyl methacrylate, tetrahydrofurfuryl methacrylate and tetrahydropyranyl methacrylate. Example of suitable acrylate esters include, without limitation, methyl acrylate, ethyl acrylate, n-propyl acrylate, isopropyl acrylate, n-butyl acrylate (BA), n-decyl acrylate, isobutyl acrylate, n-amyl acrylate, n-hexyl acrylate, isoamyl acrylate, 2-hydroxyethyl acrylate, 2-hydroxypropyl acrylate, N,N-dimethylaminoethyl acrylate, N,N-diethylaminoethyl acrylate, t-butylaminoethyl acrylate, 2-sulfoethyl acrylate, trifluoroethyl acrylate, glycidyl acrylate, benzyl acrylate, allyl acrylate, 2-n-butoxyethyl acrylate, 2-chloroethyl acrylate, sec-butyl-acrylate, tert-butyl acrylate, 2-ethylbutyl acrylate, cinnamyl acrylate, crotyl acrylate, cyclohexyl acrylate, cyclopentyl acrylate, 2-ethoxyethyl acrylate, furfuryl acrylate, hexafluoroisopropyl acrylate, methallyl acrylate, 3-methoxybutyl acrylate, 2-methoxybutyl acrylate, 2-nitro-2-methylpropyl acrylate, n-octylacrylate, 2-ethylhexyl acrylate, 2-phenoxyethyl acrylate, 2-phenylethyl acrylate, phenyl acrylate, propargyl acrylate, tetrahydrofurfuryl acrylate and tetrahydropyranyl acrylate.

The relative amount of DPGDA and urethane acrylate oligomer are controlled, so that the DPGDA is present in an amount of 0.5 to 99.5%, optionally 20 to 80% by weight based on the total amount of DPGDA and urethane acrylate oligomer. Optionally, the composition may include 10 to 90, 20 to 80, 25 to 75, 30 to 70, or 40 to 60% by weight of DPGDA, based on the combination of DPGDA and urethane acrylate oligomer.

In embodiments of the invention, the DPGDA is present in the composition in an amount of about 15 wt % to about 40 wt %, based on the total weight of the composition. In another embodiment, the one or more urethane acrylate oligomers are present in the composition in an amount of at least 55 wt % based on the total weight of the composition, for example from 55 wt % to 95 wt %.

The compositions may include one or more photoinitiators. Suitable photoinitiators include, but are not limited to, bis(2,4,6-trimethylbenzoyl)-phenylphosphine oxide, 2,4,6-trimethylbenzoylphenyl phosphinate, bis(2,6-dimethoxybenzoyl)-2,4,4-trimethylpentylphosphine oxide, diphenyl(2,4,6-trimethylbenzoyl)phosphine oxide, alpha-hydroxy cyclohexyl phenyl ketone, 2-hydroxy-1-(4-(4-(2-hydroxy-2-methylpropionyl)benzyl)phenyl-2-methylpropan-1-one, 2-hydroxy-2-methyl-1-phenylpropanone, 2-hydroxy-2-methyl-1-(4-isopropylphenyl)propanone, oligo (2-hydroxy-2-methyl-1-(4-(1-methylvinyl)phenyl)propanone, 2-hydroxy-2-methyl-1-(4-dodecylphenyl)propanone, 2-hydroxy-2-methyl-1-[(2-hydroxyethoxy)phenyl]propanone, benzophenone, substituted benzophenones, and mixtures of any two or more thereof. In any embodiments, the one or more photoinitiators may be diphenyl(2,4,6-trimethylbenzoyl)phosphine oxide, ethyl(2,4,6-trimethylbenzoyl)phenylphosphinate, 1-hydroxycyclohexylphenylketone, and combinations of two or more thereof.

In any embodiments, the one or more photoinitiators may be present in an amount of about 0.01 wt. % to about 6.0 wt. % of the total weight of the composition. Suitable amounts of the photoinitiator include, but are not limited to, about 0.01 wt. % to about 6.0 wt. %, about 0.1 wt. % to about 4.0 wt. %, about 0.20 wt. % to about 3.0 wt. %, or about 0.5 wt. % to about 1.0 wt. %, or about 1 to 2 wt %, based on the photopolymerizable composition. In one embodiment, the photoinitiator is present in an amount from 0.25 wt. % to about 2.0 wt. %. In another embodiment, the photoinitiator is present in an amount from 0.5 wt. % to about 1.0 wt. %.

According to any embodiments, the compositions may further include a solvent. Suitable solvents include, but are not limited to, propylene glycol monomethyl ether acetate, tripropylene glycol methyl ether, tripropylene glycol n-butyl ether, propylene glycol methyl ether, propylene glycol phenyl ether, propylene glycol n-butyl ether, propylene glycol diacetate, dipropylene glycol methyl ether, dipropylene glycol n-propyl ether, dipropylene glycol n-butyl ether, dipropylene glycol dimethyl ether, and mixtures of two or more thereof.

According to any embodiments, the compositions may further include nanoparticles. Suitable nanoparticles include, but are not limited to, organocation-modified phyllosilicates, TiO₂, ZnO, Ag, SiO₂, Fe₃O₄, CaCO₃, Al₂O₃, Mg(OH)₂, Al(OH)₃, CeO₂, MnO₂, cellulose, graphene, carbon fiber, carbon nanotube, cloisite, montmorillonite, hectorite, saponite, or the like and mixtures of two or more thereof. In any embodiments, the nanoparticle may be an organocation-modified phyllosilicate. In any embodiments, the organocation-modified phyllosilicate is alkylammonium cation exchanged montmorillonite.

According to any embodiments, the compositions may further include performance modifiers. Suitable performance modifiers include, but are not limited to, thiols, silyl acrylates, and thiol-functional silanes. In any embodiments, the performance modifier is a thiol. For example, suitable thiols include, but are not limited to, 1-pentanethiol, 1-hexanethiol, 1-heptanethiol, 1-octanethiol, 1-decanethiol, 1-dodecanethiol, 1-hexadecanethiol, 1-octadecanethiol, cyclohexanethiol, eicosanethiol, docosanethiol, tetracosanethiol, hexacosanethiol, octacosanethiol, t-dodecyl mercaptan, methyl thioglycolate, methyl-3-mercaptopropionate, ethyl thioglycolate, butyl thioglycolate, butyl-3-mercaptopropionate, isooctyl thioglycolate, isooctyl-3-mercaptopropionate, isodecyl thioglycolate, isodecyl-3-mercaptopropionate, dodecyl thioglycolate, dodecyl-3-mercaptopropionate, octadecyl thioglycolate, octadecyl-3-mercaptopropionate, thiogly colic acid, 3-mercaptopropionic acid, and mixtures of two or more thereof.

In any embodiments, the performance modifier may be a thio-functional silane. For example, suitable thio-functional silanes include, but are not limited, bis(3-triethoxysilylpropyl)-tetrasulfide, gamma-mercaptopropyltimethoxysilane, gamma-mercaptopropyl-triethoxysilane, and mixtures of two or more thereof.

According to any embodiments, the composition may further include ethylenically functional or non-functional non-urethane oligomers, which may further enhance the mechanical and chemical properties of the composition of the present technology. Suitable non-urethane oligomers include, but are not limited to, epoxy, ethoxylated or propoxylated epoxy resins, polyesters, polyethers, polyketones, and mixtures of two or more thereof.

Applying the composition to obtain the three-dimensional article may include depositing the composition. In any embodiments, the application may include depositing a first layer of the composition and second layer of the composition to the first layer and successive layers thereafter to obtain a 3D article. Such depositing may include one or more methods, including but not limited to, UV inkjet printing, SLA, continuous liquid interface production (CLIP), and DLP. Other applications for the compositions include, but are not limited to, other coating and ink applications for printing, packaging, automotive, furniture, optical fiber, and electronics.

The methods described herein include contacting the layers of the composition with ultraviolet light irradiation to induce curing of the composition. In any embodiments, the contacting includes short wavelength and long wavelength ultraviolet light irradiation. Suitable short wavelength ultraviolet light irradiation includes UV-C or UV-B irradiation. In one embodiment, the short wavelength ultraviolet light irradiation is UV-C light. Suitable longwave ultraviolet light irradiation includes UV-A irradiation. Additionally, Electron Beam (EB) irradiation may be utilized to induce curing of the composition.

The methods described herein include repeating the deposition of layers of the composition and exposure to UV irradiation to obtain the 3D article. In any embodiments, the repeating may occur sequentially wherein depositing the layers of composition is repeated to obtain the 3D article prior to exposure to UV irradiation. In any embodiments, the repeating may occur subsequently wherein the deposing the layers of composition and exposure to UV irradiation are repeated after both steps.

In another related aspect, a 3D article is provided that includes UV cured successive layers of the any of the compositions as described herein. In any embodiments, the composition may have been inkjet, SLA, or DLP deposited.

In any embodiments, the 3D article may include a polishing pad. In any embodiments, polishing pad is a chemical mechanical polishing (CMP) pad. Polishing pads may be made following any known methods, for example the methods provided in U.S. Patent Appl. No. 2016/0107381, U.S. Patent Appl. No. 2016/0101500, and U.S. Pat. No. 10,029,405 (each incorporated herein by reference).

The 3D article of the present technology exhibits improved toughness. In any embodiments, the three-dimensional article may, for example, exhibit a tensile strength of 56 to 75 MPa, or optionally 26 to 55 MPa. The three-dimensional article may optionally have an impact strength of 15 to 80 J/m or optionally 13 to 54 J/m.

The present technology, thus generally described, will be understood more readily by reference to the following examples, which are provided by way of illustration and are not intended to be limiting of the present invention.

### Examples

All photocurable resins described in the Examples herein contained the described oligomeric material and monomers disclosed therein in the listed amounts relative to one another (percentages given are based on the total of oligomer and monomer). In addition, each of the compositions contained 1% by weight of diphenyl(2,4,6trimethylbenzoyl)phosphine oxide as photoinitiator, based on the total weight of the compositions.

The photocurable resins used for the examples below were printed using a material development kit (MDK) Digital Light Processing (DLP) 3D printer from the company Origin at a wavelength of 385 nm for an intensity of 8.5 mW/cm² a layer thickness/resolution of 100 microns per layer and a curing time per layer of 1 s (for a few exception where curing did not occur the exposure time was increase up to 3 s/layer). First 400 mu (four layers) were printer with a respective higher exposition time of 30 s, 15 s, 15 s, and 15 s) to promote the adhesion to the moving platform in the z direction. A 170 micron PTFE membrane was used in the tray holding the resin.

All testing for mechanical properties was done using an Instron machine for both tensile and impact mechanical tests according to ASTM D638 v5 and ASTM D256. Results are the average of 8 measurements from which average and standard deviation were calculated and are reported in the examples set forth herein.

The following abbreviations and terms are used herein:

DPGDA: dipropylene glycol diacrylate

DEGDA: ditheylene glycol diacrylate

GPTA: propoxylated (3.8) glycerol triacrylate

EOEOEA: 2-(2-ethoxyethoxy)ethylacrylate

PPTTA: Ethoxylated (5.0) pentaerythritol tetraacrylate

### Example 1: DPGDA with Urethane Acrylate Oligomer 1 (UA1)

Urethane Acrylate Oligomer 1 is a urethane acrylate oligomer made a 2-propenoic acid, 2-hydroxyethyl ester polymer with 1,3-diisocyanatomethylbenzene and α-hydro-ω-hydroxypoly[oxy(methyl-1,2-ethanediyl)]. It is represented by the following formula:

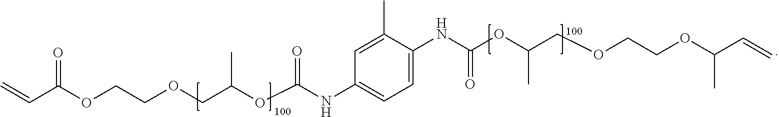

Compositions were prepared by mixing Urethane Acrylate Oligomer 1 with DPGDA and photoinitiator. These compositions were made into a 3D object with the parameters set forth above. They were then tested for tensile strength, elongation, E-modulus, and notched impact strength. The results are set forth in Table 1 below. The amounts of DPGDA and Urethane Acrylate Oligomer 1 are weight percent based on the total of DPGDA and Urethane Acrylate Oligomer 1.

TABLE 1
Results for Combination of DPGDA
and Urethane Acrylate Oligomer 1

| | | Tensile | | | |
|---|---|---|---|---|---|
| | | Strength | Elongation | E-modulus | Notched Impact |
| DPGDA | UA1 | (MPa) | (%) | (MPa) | Strength (J/m) |
| 0 | 100 | 8.7 | 37.2 | 19.6 | N/A* |
| 25 | 75 | 26 | 29.9 | 169.5 | 79.8 |
| 30 | 70 | 27 | 23.7 | 290.3 | 70.7 |
| 40 | 60 | 32 | 16.3 | 559 | 49.5 |
| 50 | 50 | 40 | 14.3 | 879 | 25.9 |
| 60 | 40 | 44 | 9.1 | 1180 | 22.7 |
| 70 | 30 | 51 | 6.6 | 1542 | 19.9 |
| 75 | 25 | 55 | 5.2 | 1752 | 15.2 |

*= only two bars printed.

### Example 2: DPGDA with Urethane Acrylate Oligomer 2 (UA1)

Urethane Acrylate Oligomer 2 is a 2-propenoic acid, 2-hydroxyethyl ester polymer with 1,1′-methylenebis[4-isocyanatocyclohexane] and 2-oxepanone, sold for example as Laromer UA 9089.

Compositions were made by mixing Urethane Acrylate Oligomer 2 with DPGDA and photoinitiator. These compositions were made into a 3D object with the parameters set forth above. They were then tested for tensile strength, elongation, E-modulus, and notched impact strength. The results are set forth in Table 2 below. The amounts of DPGDA and Urethane Acrylate Oligomer 2 are weight percent based on the total of DPGDA and Urethane Acrylate Oligomer 2.

TABLE 2
Results for Combination of DPGDA
and Urethane Acrylate Oligomer 2

| | | Tensile | | | |
|---|---|---|---|---|---|
| | | Strength | Elongation | E-modulus | Notched Impact |
| DPGDA | UA2 | (MPa) | (%) | (MPa) | Strength (J/m) |
| 0 | 100 | 35 | 30.0 | — | — |
| 20 | 80 | 49 | 20.5 | 1389 | 65 |
| 25 | 75 | 56 | 15.8 | 1589 | 62 |
| 30 | 70 | 59 | 13.9 | 1726 | 52 |
| 40 | 60 | 58 | 9.0 | 1788 | 38 |
| 50 | 50 | 63 | 8.0 | 1983 | 28 |
| 60 | 40 | 68 | 5.0 | 2146 | 22 |
| 70 | 30 | 75 | 4.1 | 2334 | 14 |
| 75 | 25 | 75 | 4.1 | 2405 | 13 |

In a similar experiment, DPGDA was combined with Urethane Acrylate Oligomer 2 and an aromatic epoxy acrylate oligomer (sold as LAROMER LR 8986). The specified amounts are based on the total amount of DPGDA, Urethane Acrylate Oligomer 2, and epoxy acrylate oligomer (weight percent). The units are the same and test methods were the same

| | | | E- | Tensile | | |
|---|---|---|---|---|---|---|
| DPGDA | UA2 | EA | modulus | Strength | Elongation | Impact |
| 25 | 37.5 | 37.5 | 2195 | 65.2 | 6 | 18.6 |
| 25 | 50 | 25 | 1915 | 87.1 | 6.7 | 26.0 |

In the below comparative examples, the same DPGDA was employed with oligomers differing from the urethane acrylate oligomers described herein.

### Comparative Example 1: DPGDA and 1,4-butanediylbis[oxy(2-hydroxy-3,1-propanediyl]diacrylate (CO1)

Compositions were made by mixing CO1 with DPGDA and photoinitiator. These compositions were made into a 3D object with the parameters set forth above. They were then tested for tensile strength, elongation, E-modulus, and notched impact strength. The results are set forth in Table 3 below. The amounts of DPGDA and CO1 are weight percent based on the total of DPGDA and CO1.

TABLE 3
Results for Combination of DPGDA and CO1

| | | Tensile | | | |
|---|---|---|---|---|---|
| | | Strength | Elongation | E-modulus | Notched Impact |
| DPGDA | CO1 | (MPa) | (%) | (MPa) | Strength (J/m) |
| 0 | 100 | 8 | 7.2 | — | 12.6 |
| 25 | 75 | 42 | 6.0 | 1359 | 13.7 |
| 50 | 50 | 57 | 5.0 | 2043 | 12.0 |
| 75 | 25 | 60 | 3.6 | 2401 | 11.7 |

### Comparative Example 2: DPGDA and Comparative Oligomer 2

Comparative Oligomer 2 (CO2) is a polyester resin made from 2,2-bis(acryloyloxymethyl)butyl acrylate and trimethylolpropane triacrylate, sold for example as LAROMER® PR 9119.

Compositions were made by mixing CO2 with DPGDA and photoinitiator. These compositions were made into a 3D object with the parameters set forth above. They were then tested for tensile strength, elongation, E-modulus, and notched impact strength. The results are set forth in Table 4 below. The amounts of DPGDA and CO2 are weight percent based on the total of DPGDA and CO2.

TABLE 4
Results for Combination of DPGDA and CO2

| | | Tensile | | | |
|---|---|---|---|---|---|
| | | Strength | Elongation | E-modulus | Notched Impact |
| DPGDA | CO2 | (MPa) | (%) | (MPa) | Strength (J/m) |
| 0 | 100 | 51 | 1.8 | 3863 | Brittle |
| 25 | 75 | 54 | 1.9 | 3584 | Brittle |
| 50 | 50 | 72 | 2.7 | 3327 | Brittle |
| 75 | 25 | 69 | 2.9 | 2981 | Brittle |

### Comparative Example 3: DPGDA and Comparative Oligomer 3

Comparative Oligomer 3 (CO3) is an unsaturated polyester resin made from 1,3-isobenzofurandione, 3a,4,7,7α-tetrahydro polymer with 2,5-furandione and 2,2′-oxybis[ethanol], sold for example as LAROMER® UP 9118.

Compositions were made by mixing CO3 with DPGDA and photoinitiator. These compositions were made into a 3D object with the parameters set forth above. They were then tested for tensile strength, elongation, E-modulus, and notched impact strength. The results are set forth in Table 5 below. The amounts of DPGDA and CO3 are weight percent based on the total of DPGDA and CO3.

TABLE 5
Results for Combination of DPGDA and CO3

| | | Tensile | | | |
|---|---|---|---|---|---|
| | | Strength | Elongation | E-modulus | Notched Impact |
| DPGDA | CO3 | (MPa) | (%) | (MPa) | Strength (J/m) |
| 0 | 100 | 54 | 3.5 | 2021 | Brittle |
| 25 | 75 | 65 | 3.5 | 2549 | 12.3 |
| 50 | 50 | 69 | 3.5 | 2672 | 12.0 |
| 75 | 25 | 71 | 3.5 | 2681 | Brittle |

Compositions were made by mixing CO2 with DPGDA and photoinitiator. These compositions were made into a 3D object with the parameters set forth above. They were then tested for tensile strength, elongation, E-modulus, and notched impact strength. The results are set forth in Table 3 below. The amounts of DPGDA and CO2 are weight percent based on the total of DPGDA and CO2.

TABLE 3
Results for Combination of DPGDA and CO2

| | | Tensile | | | |
|---|---|---|---|---|---|
| | | Strength | Elongation | E-modulus | Notched Impact |
| DPGDA | CO2 | (MPa) | (%) | (MPa) | Strength (J/m) |
| 0 | 100 | 51 | 1.8 | 3863 | Brittle |
| 25 | 75 | 54 | 1.9 | 3584 | Brittle |
| 50 | 50 | 72 | 2.7 | 3327 | Brittle |
| 75 | 25 | 69 | 2.9 | 2981 | Brittle |

### Comparative Example 4: DPGDA and Comparative Oligomer 4

Comparative Oligomer 4 (C04) is a polyisocyanate having 2 acrylate groups and 3 NCO groups, sold for example as LAROMER® PR 9000. The same procedure was utilized to make compositions combining DPGDA and C04. The results are set forth in Table 6 below. The amounts of DPGDA and C04 are weight percent based on the total of DPGDA and C04.

TABLE 6
Results for Combination of DPGDA and CO4

| | | Tensile | | | |
|---|---|---|---|---|---|
| | | Strength | Elongation | E-modulus | Notched Impact |
| DPGDA | CO4 | (MPa) | (%) | (MPa) | Strength (J/m) |
| 0 | 100 | — | — | * | 25.8 |
| 25 | 75 | 60 | 5.0 | 1714 | 17.6 |
| 50 | 50 | 77 | 4.2 | 2428 | 12.7 |
| 75 | 25 | 71 | 4.6 | 2581 | 11.8 |

*invalid test: crushed into power

### Comparative Example 5: DPGDA and Comparative Oligomer 5

Comparative Oligomer 5 (C05) is an oligomer of propylidynetrimethanol, ethoxylated, esters with acrylic acid (>1<6.5 mol EO), sold for example as LAROMER® LR 8986. The same procedure was utilized to make compositions combining DPGDA and C05. The results are set forth in Table 7 below. The amounts of DPGDA and C05 are weight percent based on the total of DPGDA and C05.

TABLE 7
Results for Combination of DPGDA and CO5

| | | Tensile | | | |
|---|---|---|---|---|---|
| | | Strength | Elongation | E-modulus | Notched Impact |
| DPGDA | CO5 | (MPa) | (%) | (MPa) | Strength (J/m) |
| 0 | 100 | 79 | 4.1 | 2734 | 11.9 |
| 25 | 75 | 76 | 4.2 | 2694 | 12.8 |
| 50 | 50 | 71 | 3.7 | 2656 | 12.8 |
| 75 | 25 | 65 | 3.5 | 2601 | 11.3 |

### Comparative Example 6: DPGDA and Comparative Oligomer 6

Comparative Oligomer 6 (C06) is a polyester acrylate oligomer made from hexanedioic acid polymer with 2-(chloromethyl)oxirane, 2-ethyl-2-(hydroxymethyl)-1,3-propanediol, 4,4′-) 1-methylethylidene)bis[phenol] and oxirane, 2-propenoate, sold for example as LAROMER® PE 9074. The same procedure was utilized to make compositions combining DPGDA and C06. The results are set forth in Table 8 below. The amounts of DPGDA and C06 are weight percent based on the total of DPGDA and C06.

TABLE 8
Results for Combination of DPGDA and CO6

| | | Tensile | | | |
|---|---|---|---|---|---|
| | | Strength | Elongation | E-modulus | Notched Impact |
| DPGDA | CO6 | (MPa) | (%) | (MPa) | Strength (J/m) |
| 0 | 100 | 16 | 15.3 | 91.8 | 26.6 |
| 25 | 75 | 36 | 11.8 | 919.5 | 20.9 |
| 50 | 50 | 44 | 4.1 | 1666 | 14.5 |
| 75 | 25 | 58 | 5.4 | 2222 | 11.8 |

### Comparative Example 7: GPTA and Urethane Acrylate Oligomer 2

Compositions were prepared by mixing Urethane Acrylate Oligomer 2 as set forth in Example 2 with GPTA (a trifunctional acrylate monomer) and photoinitiator. These compositions were made into a 3D object with the parameters set forth above. They were then tested for tensile strength, elongation, E-modulus, and notched impact strength. The results are set forth in Table 9 below. The amounts of GPTA and Urethane Acrylate Oligomer 2 are weight percent based on the total of GPTA and Urethane Acrylate Oligomer 2.

TABLE 9
Results for Combination of GPTA and UA2

| | | Tensile | | | |
|---|---|---|---|---|---|
| | | Strength | Elongation | E-modulus | Notched Impact |
| GPTA | UA2 | (MPa) | (%) | (MPa) | Strength (J/m) |
| 30 | 70 | 43 | 16.6 | 1060 | 69 |
| 50 | 50 | 50 | 10.7 | 1461 | 57 |
| 70 | 30 | 58 | 6.3 | 1658 | 24 |

### Comparative Example 8: PPTTA and Urethane Acrylate Oligomer 2

Compositions were prepared by mixing Urethane Acrylate Oligomer 2 as set forth in Example 2 with PPTTA (a tetrafunctional acrylate monomer) and photoinitiator. These compositions were made into a 3D object with the parameters set forth above. They were then tested for tensile strength, elongation, E-modulus, and notched impact strength. The results are set forth in Table 10 below. The amounts of PPTTA and Urethane Acrylate Oligomer 2 are weight percent based on the total of PPTTA and Urethane Acrylate Oligomer 2.

TABLE 10
Results for Combination of PPTTA and UA2

| | | Tensile | | | |
|---|---|---|---|---|---|
| | | Strength | Elongation | E-modulus | Notched Impact |
| PPTTA | UA2 | (MPa) | (%) | (MPa) | Strength (J/m) |
| 30 | 70 | 52 | 13.3 | 1311 | 30.6 |
| 50 | 50 | 60 | 7.7 | 1624 | 17.8 |
| 70 | 30 | 74 | 5.8 | 1915 | 12.5 |

### Comparative Example 9: EOEOEA with Urethane Acrylate Oligomer 2

Compositions were prepared by mixing Urethane Acrylate Oligomer 2 as set forth in Example 2 with EOEOA (a monofunctional acrylate monomer) and photoinitiator. These compositions were made into a 3D object with the parameters set forth above. Three compositions were tested, with the first having 30 wt % EOEOEA and 70 wt % UA2, the seonc having 50 wt % EOEOEA and 50 wt % UA2, and the third having 70 wt % EOEOEA and 30 wt % UA2, in each case based on the amount of UA2 and EOEOEA. In each case, testing was rendered impossible as the resultant article was crushed into powder during tensile testing.

As seen above, by combining DPGDA with urethane acrylate oligomers, it was possible to produce articles that exhibited sufficient toughness with only a single monomer and oligomer, while maintaining requisite processability. The same effects were not seen when DPGDA were combined with differing oligomers, or where monofunctional or tri or tetrafunctional acrylate monomers differing from DPGDA were used.

Preferred embodiments of this invention are described herein, including the best mode known to the inventors for carrying out the invention. It will be appreciated that the invention is not restricted to the details described above with reference to the preferred embodiments but that numerous modifications and variations can be made without departing from the spirit and scope of the invention as defined by the following claims.

1.-19. (canceled)

20. A photopolymerizable composition comprising:
dipropylene glycol diacrylate; and
at least one urethane acrylate oligomer.

21. The photopolymerizable composition according to claim 20, wherein the at least one urethane acrylate oligomer is represented by Formula (I): 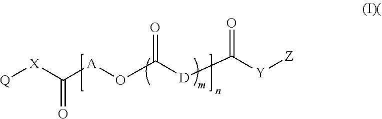
wherein:
A is derived from one or more poly hydroxyl group compounds having a molecular weight less than about I 000 g/mol;
D, X, and Y are independently urethane or carbamate linkages derived from one or more polyisocyanates;
Q and Z are independently derived from one or more compounds having at least one ethylenically unsaturated group;
n is an integer from 1 to 20; and
m is an integer from 0 to 20.

22. The photopolymerizable composition according to claim 20, wherein the composition comprises 0.5 to 99.5% by weight dipropylene glycol diacrylate, based on the amount of dipropylene glycol diacrylate and urethane acrylate oligomer.

23. The photopolymerizable composition according to claim 20, wherein the composition comprises 25 to 75% by weight dipropylene glycol diacrylate, based on the amount of dipropylene glycol diacrylate and urethane acrylate oligomer.

24. The photopolymerizable composition according to claim 20, wherein the composition further comprises one or more photoinitiators.

25. The photopolymerizable composition according to claim 20, wherein the one or more photoinitiators is selected from the group consisting of bis(2,4,6-trimethylbenzoyl)-phenylphosphine oxide, 2,4,6-trimethylbenzoylphenyl phosphinate, bis(2,6-dimethoxybenzoyl)-2,4,4-trimethylpentylphosphine oxide, diphenyl(2,4,6-trimethylbenzoyl)phosphine oxide, alpha-hydroxy cyclohexyl phenyl ketone, 2-hydroxy-1-(4-(4-(2-hydroxy-2-methylpropionyl)benzyl)phenyl-2-methylpropan-1-one, 2-hydroxy-2-methyl-1-phenylpropanone, 2-hydroxy-2-methyl-1-(4-isopropylphenyl)propanone, oligo (2-hydroxy-2-methyl-1-(4-(1-methylvinyl)phenyl)propanone, 2-hydroxy-2-methyl-1-(4-dodecylphenyl)propanone, 2-hydroxy-2-methyl-1-[(2-hydroxyethoxy)phenyl]propanone, benzophenone, substituted benzophenones, and mixtures of any two or more thereof.

26. The photopolymerizable composition according to claim 25, wherein the one or more photoinitiators are selected from the group consisting of diphenyl(2,4,6-trimethylbenzoyl)phosphine oxide, ethyl(2,4,6-trimethylbenzoyl)phenylphosphinate, 1-hydroxycyclohexylphenylketone, and combinations of two or more thereof.

27. The photopolymerizable composition according to claim 25, wherein the one or more photoinitiators are present in the composition in an amount of from 0.01 to 6 weight percent, based on the total weight of the composition.

28. The photopolymerizable composition according to claim 25, wherein the one or more photoinitiators are present in the composition in an amount of from 1 to 2 weight percent, based on the total weight of the composition.

29. The photopolymerizable composition according to claim 20, wherein DPGDA is the sole monomer present in the composition.

30. The photopolymerizable composition according to claim 29, wherein the one or more urethane acrylate oligomers are the sole oligomers present in the composition.

31. The photopolymerizable composition according to claim 26, wherein the composition consists of the DPGDA, the one or more urethane acrylate oligomer, and the one or more photoinitiators.

32. The photopolymerizable composition according to claim 20, wherein the composition further comprises a solvent.

33. A package comprising the composition of claim 20.

34. A method of preparing a three-dimensional article, wherein the method comprises applying successive layers of one or more of the compositions of claim 20 to fabricate a three-dimensional article, and irradiating the successive layers with UV irradiation.

35. The method of claim 34, wherein the applying comprises depositing a first layer of the composition to a substrate and applying a second layer of the composition to the first layer and optionally applying successive layers thereafter.

36. The method of claim 34, wherein the applying comprises ink jet printing of the composition.

37. A three-dimensional article comprising UV cured successive layers of the composition of claim 20.

38. A three-dimensional article produced by the method of claim 34.
